(19) United States
(12) Patent Application Publication
(10) Pub. No.: US 2023/0317694 A1
(43) Pub. Date: Oct. 5, 2023

(54) ARCHITECTURE AND DEVICE USING OPTICAL ELEMENT AND COMPUTER CHIP FOR OPTICAL SIGNAL TRANSMISSION

(71) Applicant: International Business Machines Corporation, Armonk, NY (US)

(72) Inventors: Frank Robert Libsch, White Plains, NY (US); Kamal K. Sikka, Poughkeepsie, NY (US); Arvind Kumar, Chappaqua, NY (US)

(21) Appl. No.: 17/657,767

(22) Filed: Apr. 4, 2022

(51) Int. Cl. H01L 25/16; H01L 23/538; H01L 33/58; H01L 31/0232

(52) U.S. Cl. CPC H01L 25/167; H01L 23/5385; H01L 33/58; H01L 31/02327; H04B 10/672

(57) ABSTRACT

A device and associated method include using an optical element (OE) for electrical and optical communications on the device. A substrate includes a wiring layer with an optically transparent path which allows optical signals to pass therethrough. An optical coupling layer is coupled to the wiring layer, and the optical coupling layer includes at least one micro-lens for focusing or collimating the optical signals through the transparent path. An OE is coupled to the wiring layer, and the OE is positioned in optical alignment with the optically transparent path for communicating optical signals. One or more semiconductor chips can be communicatively coupled to an OE for controlling the OE.

### BACKGROUND

The present disclosure relates to devices including optical elements (OEs) for electrical and optical communications, for example, on a semiconductor device or chip.

Known in the field of semiconductor technology including integrated circuit processing for microchips is a host chip and various reshaping transmitter and receiver circuits and techniques that correct for electrically distorted channel signals.

In one example, a method of using optical elements on a semiconductor chip with a carrier can include an optical element with micro-resonator rings (MRRs). The method can include a two-step error detection process, where the first step is to send a “1” data string between channels and using a parity function to detect faulty signals (optical power degradation). The method can include iterating through redundant slightly offset narrow operation wavelength MRRs at the receivers.

### SUMMARY

The present disclosure recognizes the shortcomings and problems associated with current techniques for electrical and optical communications on a semiconductor device or chip using optical elements and electrical wiring.

The present invention can include an embedded carrier where optical-to-electrical conversion devices (O/Es) operate with a shortened high speed electrical channel between the host chip and the E/Os on the new optical element (OE) structure to reduce the need for various reshaping transmitters and receiver circuits and other techniques that correct for electrically distorted channel signals. The circuit reduction/elimination according to the present disclosure can be beneficial in the reduction of energy and heat. The power saving architecture of the OE structure according to the present disclosure can reduce optical power compared to a conventional optical drive, which is accomplished by a direct drive architecture.

The present invention can include a method including a single step process that does not need to cycle through structures (micro-resonator rings, MRRs, and optical channels) to find workable optical channels as a function of temperature. Connections are done on the fly advancing to the next workable optical channel. The method can include addressing O/E failures via more robust electrical determined paths versus temperature dependent optical path/structures (MRRs). The method can be compatible for single-mode and multi-mode wavelengths.

Additionally, the method is compatible with optical channel hardware, as well as fibers channels and/or connectors.

In one example, a device can include an OE or OE structure which includes an optical-to-electrical (O/E) and/or an electrical-to-optical (E/O) conversion device on a device.

In an aspect according to the present invention, a device includes an OE or OE structure for electrical and optical communications on the device. The OE structure includes a substrate which includes a wiring layer with an optically transparent path which allows optical signals to pass therethrough. The OE structure includes an optical coupling layer coupled to the wiring layer, and the optical coupling layer includes at least one micro-lens for focusing or collimating the optical signals through the transparent path, and at least one optical-to-electrical (O/E) or electrical-to-optical (E/O) conversion device. The structure includes a carrier electrically attached to the wiring layer, and a first OE coupled to the wiring layer. The first OE is positioned in optical alignment with the optically transparent path for communicating optical signals. The device includes one or more semiconductor chips being communicatively coupled to the first OE, and the one or more semiconductor chips control the first OE

In a related aspect, the communicating of the optical signals includes receiving or sending of the optical signals.

In a related aspect, the electrically attaching of the wiring layer to the carrier includes using one or more bonding pads.

In a related aspect, the electrically attaching of the wiring layer to the carrier includes using one or more bonding pads, and the one or more bonding pads being attached to one end of the wiring layer, and the first OE element coupled to another end of the wiring layer with respect to the one or more bonding pads.

In a related aspect, the device further includes a second OE coupled to a second wiring layer. The second OE is in spaced relation to the first EO along the carrier, and the second OE is positioned in optical alignment with a second optical transparent path for communicating second optical signals. The device includes another one or more semiconductor chips being communicatively coupled to the second OE, and the another one or more semiconductor chips control the second OE.

In a related aspect, the electrically attaching of the wiring layer to the carrier includes using one or more bonding pads, and the one or more bonding pads being attached to one end of the wiring layer. The first OE coupled to another end of the wiring layer with respect to the one or more bonding pads; and the device further comprises; a second OE being coupled to a second wiring layer, the second OE in spaced relation to the first EO along the carrier, and the second OE being positioned in optical alignment with a second optical transparent path for communicating second optical signals. The device includes another one or more semiconductor chips being communicatively coupled to the second OE, and the another one or more semiconductor chips control the second OE.

In a related aspect, the communicating of the first and second optical signals includes receiving or sending the first or second optical signals, respectively.

In another aspect according to the present invention, a method of optical element (OE) alignment to a lens array on a semiconductor substrate assembly for electrical and optical communications includes: forming a wiring layer on a semiconductor substrate, the wiring layer including an optically transparent path which allows optical signals to pass therethrough; coupling an optical coupling layer to the wiring layer, the optical coupling layer including at least one micro-lens for focusing or collimating the optical signals through the transparent path; electrically attaching a carrier to the wiring layer; and coupling a first OE to the wiring layer, the first OE positioned in optical alignment with the optically transparent path for communicating optical signals. The method includes communicatively coupling one or more semiconductor chips to the first OE, and the one or more semiconductor chips control the first OE.

In a related aspect, the method further includes receiving or sending of the optical signals as part of the communicating of the optical signals.

In a related aspect, the electrically attaching of the wiring layer to the carrier includes using one or more bonding pads.

In a related aspect, the electrically attaching of the wiring layer to the carrier includes using one or more bonding pads. The method further includes attaching the one or more bonding pads to one end of the wiring layer, and coupling the first OE element to another end of the wiring layer with respect to the one or more bonding pads.

In a related aspect, the method further including: coupling a second OE to a second wiring layer, the second OE in spaced relation to the first EO along the carrier; and positioning the second OE in optical alignment with a second optical transparent path for communicating second optical signals. The method includes communicatively coupling another one or more semiconductor chips to the second OE, and the another one or more semiconductor chips control the second OE.

In a related aspect, the electrically attaching of the wiring layer to the carrier includes using one or more bonding pads; and the method further including: attaching the one or more bonding pads to one end of the wiring layer; coupling the first OE to another end of the wiring layer with respect to the one or more bonding pads; coupling a second OE to a second wiring layer, the second OE in spaced relation to the first EO along the carrier; and positioning the second OE in optical alignment with a second optical transparent path for communicating second optical signals. The method including communicatively coupling another one or more semiconductor chips to the second OE, and the another one or more semiconductor chips control the second OE.

In a related aspect, the communicating of the first and second optical signals includes receiving or sending the first or second optical signals, respectively.

In another aspect according to the present disclosure, a system includes a chip package which includes a semiconductor device which includes an optical element (OE) for electrical and optical communications on the device. The system includes a semiconductor substrate which includes a wiring layer with an optically transparent path which allows optical signals to pass therethrough. An optical coupling layer is coupled to the wiring layer, and the optical coupling layer includes at least one micro-lens for focusing or collimating the optical signals through the transparent path. A carrier is electrically attached to the wiring layer, and a first OE is coupled to the wiring layer. The first OE is positioned in optical alignment with the optically transparent path for communicating optical signals. The system includes one or more semiconductor chips being communicatively coupled to the first OE, and the one or more semiconductor chips control the first OE.

In a related aspect, the communicating of the optical signals includes receiving or sending of the optical signals.

In a related aspect, the electrically attaching of the wiring layer to the carrier includes using one or more bonding pads.

In a related aspect, the electrically attaching of the wiring layer to the carrier includes using one or more bonding pads, and the one or more bonding pads being attached to one end of the wiring layer, and the first OE element coupled to another end of the wiring layer with respect to the one or more bonding pads.

In a related aspect, a second OE is coupled to a second wiring layer, the second OE is in spaced relation to the first EO along the carrier, and the second OE being positioned in optical alignment with a second optical transparent path for communicating second optical signals. The system includes another one or more semiconductor chips being communicatively coupled to the second OE, and the one or more semiconductor chips control the second OE.

In a related aspect, the electrically attaching of the wiring layer to the carrier includes using one or more bonding pads, and the one or more bonding pads being attached to one end of the wiring layer, and the first OE coupled to another end of the wiring layer with respect to the one or more bonding pads; and the device further comprises; and a second OE being coupled to a second wiring layer, the second OE in spaced relation to the first EO along the carrier, and the second OE being positioned in optical alignment with a second optical transparent path for communicating second optical signals. The system includes another one or more semiconductor chips being communicatively coupled to the second OE, and the one or more semiconductor chips control the second OE.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. The drawings are discussed forthwith below.

FIG. 1A is a schematic block diagram illustrating an overview of a system, system features or components, and methodology for electrical and optical communications on a device, according to an embodiment of the present disclosure.

FIG. 1B is a schematic block diagram illustrating a prior art system including an optical interface, according to an example embodiment.

FIG. 2 is a schematic block diagram including a side elevation view of a lens array and includes isometric views from the lens array as depicted by dotted lines in the figure, according to an embodiment of the present disclosure.

FIG. 3 is a schematic block diagram including a side elevation view of a chip including a lens array and OE structure, according to an embodiment of the present disclosure.

FIG. 4A is a bottom view of a first level interconnect of the chip shown in FIG. 3.

FIG. 4B is a cross sectional side elevational view along line A-A′ shown in FIG. 4A.

FIG. 5 is a cross sectional side elevational view along line B-B′ shown in FIG. 4A.

FIG. 6 is a cross sectional side elevational view along line C-C′ shown in FIG. 4A.

FIG. 7 is a block diagram illustrating a method and process according to an embodiment of the present invention, for electrical and optical communications on a device, according to an embodiment of the present disclosure.

FIG. 8 is a schematic block diagram including a side elevation view of a chip including a lens array and OE structure including a PCB, according to an embodiment of the present disclosure.

FIG. 9 is a flow chart block diagram for electrical and optical communications on a device, according to an embodiment of the present disclosure.

### DETAILED DESCRIPTION

The following description with reference to the accompanying drawings is provided to assist in a comprehensive understanding of exemplary embodiments of the invention as defined by the claims and their equivalents. The description includes various specific details to assist in that understanding, but these are to be regarded as merely exemplary, and assist in providing clarity and conciseness. Accordingly, those of ordinary skill in the art will recognize that various changes and modifications of the embodiments described herein can be made without departing from the scope and spirit of the invention. In addition, descriptions of well-known functions and constructions may be omitted.

The terms and words used in the following description and claims are not limited to the bibliographical meanings, but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

### EMBODIMENTS AND EXAMPLES

Embodiments and figures of the present disclosure may have the same or similar components as other embodiments. Such figures and descriptions of illustrate and explain further examples and embodiments according to the present disclosure.

Referring to the figures, according to embodiments of the present disclosure, a device includes an optical element (OE) (also referred to as an OE structure) for electrical and optical communications on the device includes features described below. It is understood that an optical element (OE), as used herein, can include an E/O (electrical to optical) conversion device, or a O/E (optical to electrical) conversion device, a semiconductor that performs an optical-to-electrical conversion and/or an electrical-to-optical conversion. The OE or OE structure may include wiring and lenses or lens arrays, etc., and either an E/O or an O/E, or both. In one example, an E/O and O/E can be a VCSEL (Vertical Cavity Self Emitting Laser), and a PD (Photo Diode), respectively.

Embodiments of the present disclosure include operational actions and/or procedures. A method can includes a series of operational blocks for implementing an embodiment according to the present disclosure which can include the systems shown in the figures. The operational blocks of the methods and systems according to the present disclosure can include techniques, mechanism, modules, and the like for implementing the functions of the operations in accordance with the present disclosure.

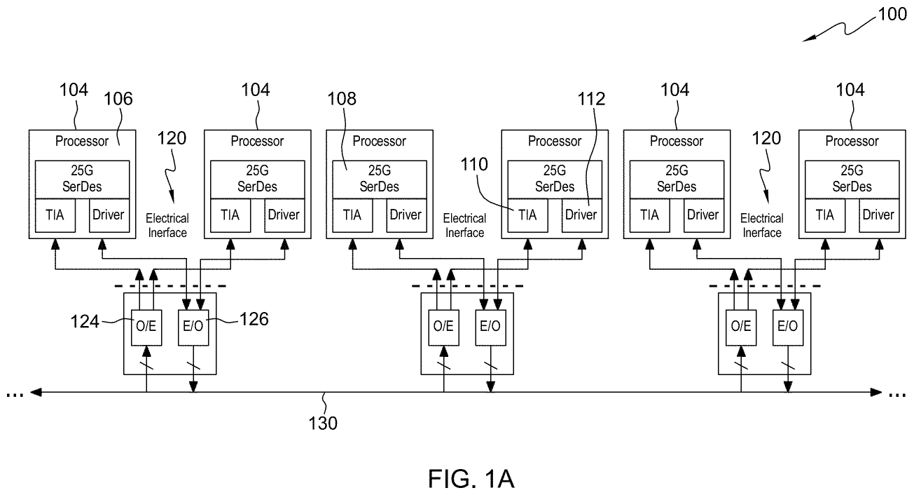

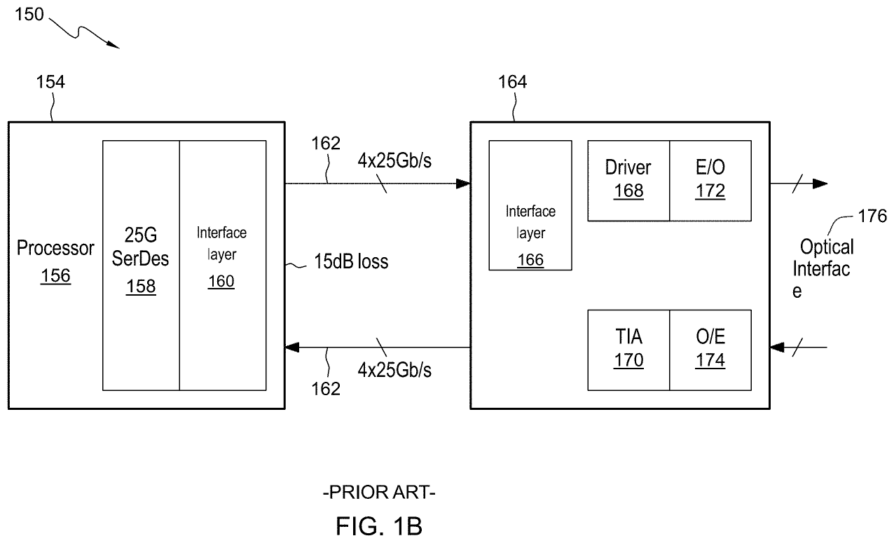

Referring to FIG. 1A, according to an embodiment of the present disclosure, a chip to wafer assembly 100 includes a host chip 104 having a processor 106. The assembly 100 shows multiple first level packages on one or more PCBs (printed circuit boards), racks, etc. The processor 106 includes a serializer/deserializer 108, for serializing and deserializing digital data using high-speed chip to chip communication. The processor 106 also includes a trans-impedance amplifier (TIA) 110 and a driver 112. The host chips 104 interface with other host chips 104 using an electrical interface 120 which can be represented as a series of host chips, for example, which can include a series of chips or an “n” number of chips, where n is an integer greater than 0. The chips 104 interface with an optical bus 130, via optical/electrical conversion devices, for example O/E 124, and E/O 126, for example, the optical bus can connect one or more first level packages within a printed circuit board (PCB), or between PCBs, between shelves, racks or systems. The electrical interfaces 120 includes an optical to electrical (O/E) device 124 and an electrical to optical device (E/O) 126 which communicate with a printed circuit board PCB 130 as shown in the assembly 100.

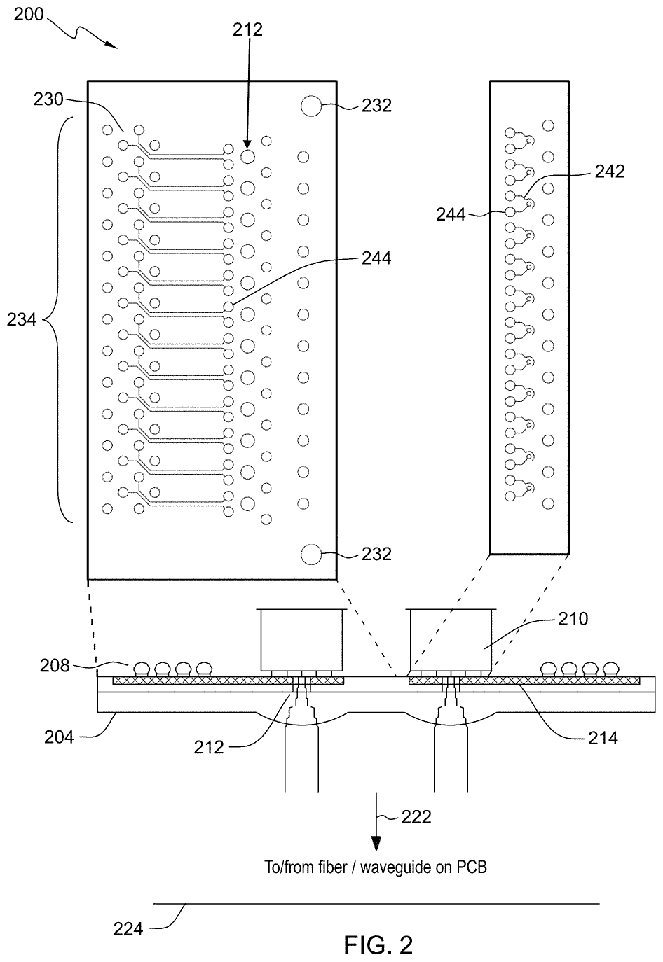

The assembly 100 may incorporate a wafer assembly O/E chips-to-wafer (O/E-to-wafer) assembly technology, with a 1st level package electrical bonding (solder reflow, etc.) of O/E and E/O chips onto metal pads. The wafer assembly can include a substrate lens and alignment feature (to PCB) (as in an example shown in FIG. 2) with an optical underfill to be a non-free space light/optical signal guide between 1st level package and PCB based optical waveguide or fiber.

An OE structure can include a wiring layer with at least one optically transparent path for allowing an optical signal to pass through. The OE structure can include an optical coupling layer attached to the wiring layer, the optical coupling layer can include at least one micro-lens for focusing or collimating the optical signal through the transparent path. One or more bonding pads are for electrically attaching the wiring layer to a carrier. At least one first OE can be coupled to the other end of the wiring layer, and the OE can be positioned in optical alignment with the optically transparent path for receiving or sending of optical signals. The OE structure using optical coupling, can eliminate optical wiring or fiber. In another embodiment, a method of OE optical I/O alignment to lens array can be implemented. In another embodiment, a system of incorporating the OE structure into a chip package can be implemented. In another embodiment, a direct drive optical sub-assembly architecture with lane sparing technique can be implemented. Embodiments according to the present disclosure for low power dissipation communication between a carrier mounted OE structure and a PCB.

Referring to FIG. 1B, a known system 150 includes a host chip 154. The host chip 154 includes a processor 156 having a serializer/deserializer 158 and an interface layer 160. An optical module 164 includes an interface layer 166, a driver 168, a TIA 170, and an E/O 172 and an O/E 174. TIA is a Trans-Impedance Amplifier, E/O is an Electrical to Optical conversion device, and OLE is Optical to Electrical conversion device. The optical module 164 communicates with an optical interface 176. In an example 100 Gb/s system 150, a medium reach (10″) interface can be used between the host chip 154 and the optical module 164. 25G IOs 162 on both ends of the electrical interface can be able to drive a channel with up to 15 dB of loss at a fundamental frequency. For 100 m links, a retiming function can be used on the optical module 164 in order to close the EOE link budget.

Referring to FIG. 2, in an embodiment of a structure 200 according to the present disclosure, includes an O/E structure showing a lens attached array with an enabled electrical I/O C4 flip chip. A lens array 204 includes C4 bonding 208. An O/E 210, which can be a front contact, front emitting, and flip chip bonded can include a transparent optical via/path 212. A metal interconnect 214 can be on an optical transparent lens. The transparent optical via 212 communicates with 222, to/from fiber/waveguide on a PCB 224.

Referring to FIG. 2, an isometric view of the lens array 204 shows the lens array cross-section (bottom) and top view (upper left) including interconnect pads 230 which communicate with a data bus 234, optical via 212, and alignment holes 232 in a lens are for precision PCB alignment pins. Bottom O/E view (upper right) of O/E pads 244 are in O/E region 242 The optical transparent lens array 204 includes OE optical transmission, and the lens may be of a material transparent at the O/Es optical wavelength. For example, thermoset or epoxy clear plastic, glass can be molded or etched to form the lens and are optically transparent over a wide wavelength spectrum from UV to infrared. For front side emitting, no restriction on optical wavelength (e.g., 850 nm, 980 nm, etc.). A separate lens can be attached (for example, using C4, etc.). For example, lenses can be concaved or convexed, focusing or collimating. Electrical contacts (via C4s, etc.) between O/Es and host chip/interposer/carrier can ensure a consistent C4 pitch & space dimension with the host packaging technology. Alignment holes, for example, can mate with PCB alignment pins such as MT Ferrule pins (Diameter 700 um+/−½ um).

An O/E can include a single or arrays of VCSELs (vertical-cavity surface-emitting laser) and/or PDs (photodiode), including multidimensional arrays. Also, may have additional support, such as, LDD/TIA (Laser Diode Driver/Trans Impedance Amplifier) circuitry or chips, which can be in near proximity to an integrated circuit. The lens array can make use of conventional thermal management via the backside of the O/Es, in addition to a thermal path via the lens C4s. Metal interconnects can be deposited and defined on glass or silicon wafers, with or without additional insulating or adhesion layers, wafer scale bonded and diced/singulated to dimensions.

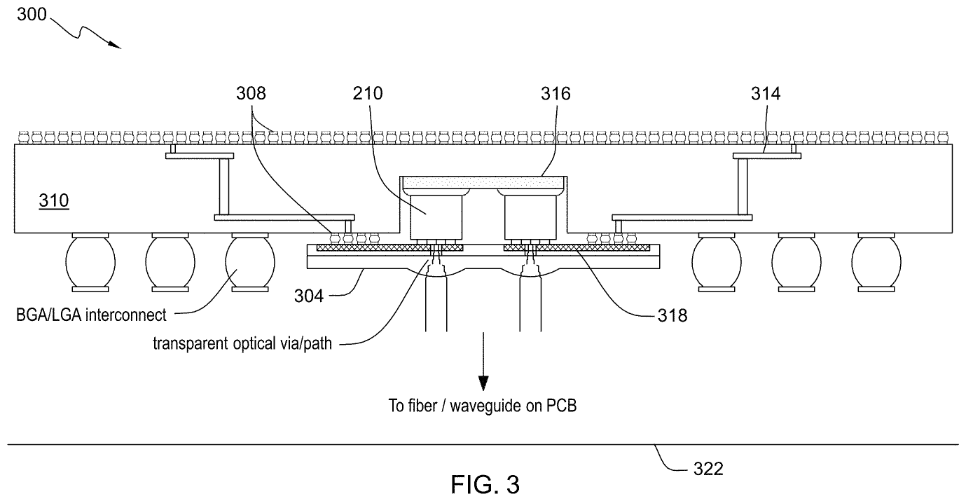

Referring to FIG. 3, in another embodiment according to the present disclosure, a substrate 300 includes a lens array 304 and O/Es 210. The lens array 304 is attached with electrical I/O C4 308 flip chip enabled into an interposer or carrier 310. The carrier 310 includes electrical interconnects 314 from the bottom side I/O C4 308 to top-side I/O C4s 3that electrically connect integrated drivers/TIAs, which may be part of semiconductor chips such as 104. The electrical interconnects 314 connect to a metal interconnect 318 on an optical transparent lens of the lens array 304 using C4s 308 connecting the carrier 310 to the lens array 304. The carrier 310 can connect to a PCB 322 using a BGA/LGA (Ball Grid Array/Land Grid Array) interconnects.

In the substrate 300 shown in FIG. 3, the thermal effects in high-speed VCSELs can be relieved by reducing the series resistance of the VCSEL, using DBRs with a high thermal conductivity, employing copper-plated heat sinks, and/or bonding VCSEL chips to efficient heat plugs. For example, a heat spreader 316 can be positioned above and in thermal communication with one or more O/Es, e.g., O/E 210. Electrical parasitics can include bonding pads and leads and can eventually limit the modulation bandwidth of a VCSEL, thus close proximity to the host driving chip is desired and obtainable using the techniques of the present disclosure.

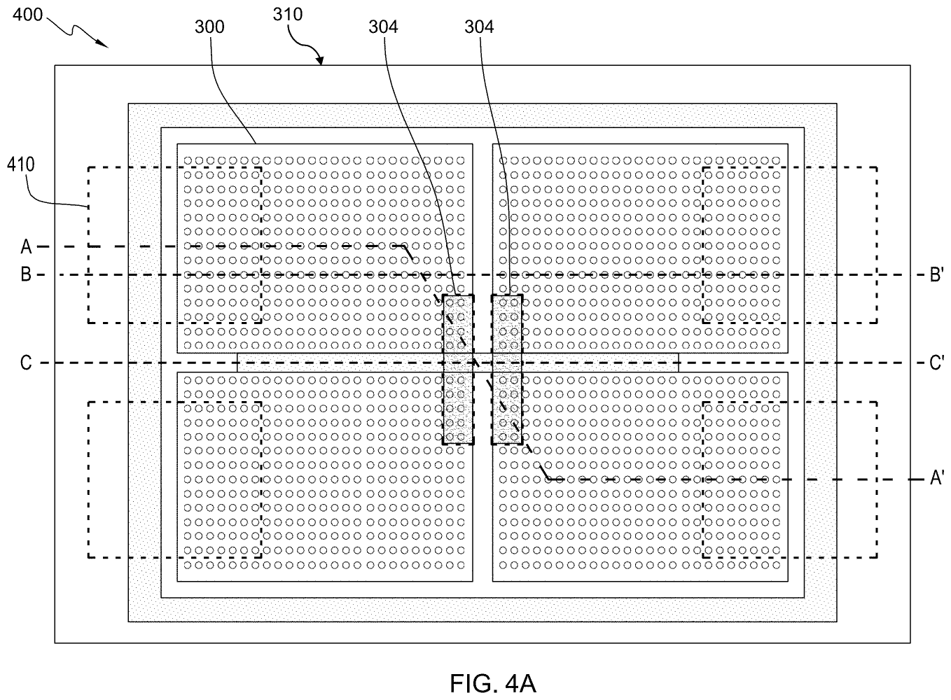

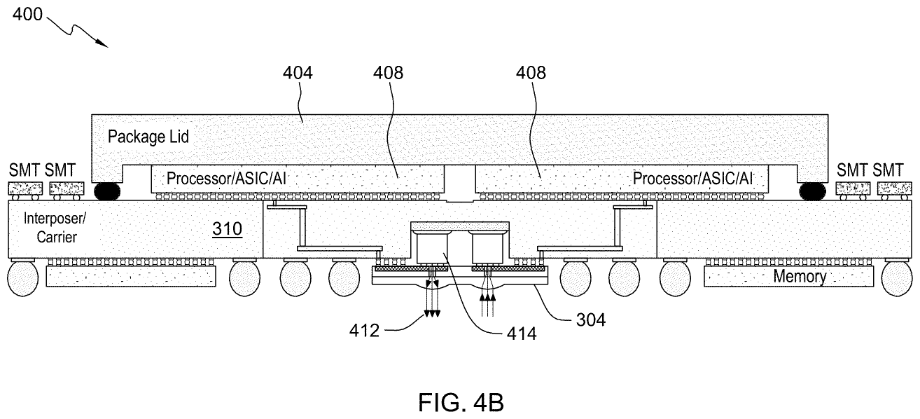

Referring to FIG. 4A, the chip 300, for example, a processor/ASIC/AI chip, can include an optical I/O (Input/Output) distributed via lens array 304 mounted on a bottom of an interposer/carrier 310. The lens array can include, for example, a VCEL with a lens array, and the alignment can be for frontside emitting. The chip can be part of a substrate package 400. The lens array 304 can be in any n×m dimension. The lens array can be focusing, and collimating, etc. The lens array can be tailored to a PCB waveguide including coupling and alignment. The lens array can be a separate lens (e.g., component) aligned or self-aligned (for example, by solder melt sideways wetting forces) to LED or a dielectric layer fabricated onto GaN LED substrate and etched to the mechanical lens focal geometry required. In another example, the array and/or bottom side chips, 410, can be attached to bottom interposer/carrier surface or recessed into interposer/carrier and/or PCB. The bottom side chips are advantageous locations that require close proximity to the host chip 408 and that also do not require as large thermal cooling mechanism, such as support memory chips 410 The lens array does not require an optical connector and/or separate mechanical mating.

Referring to the cross-section drawing in FIG. 4B, a package 400 includes a package lid 404 and processors 408 on the interposer carrier 310, showing the substrate 300 (illustrated in FIG. 3) in cross-section along line A-A′. On-carrier E/Os outgoing optical signals, 412, and O/Es incoming optical signals, 414, interface to off-package (on PCB only) WG/WG flex. The lens array is designed to either be indexed to free space or an optical underfill. The OEs can be front contact, and frontside side emitting/receiving.

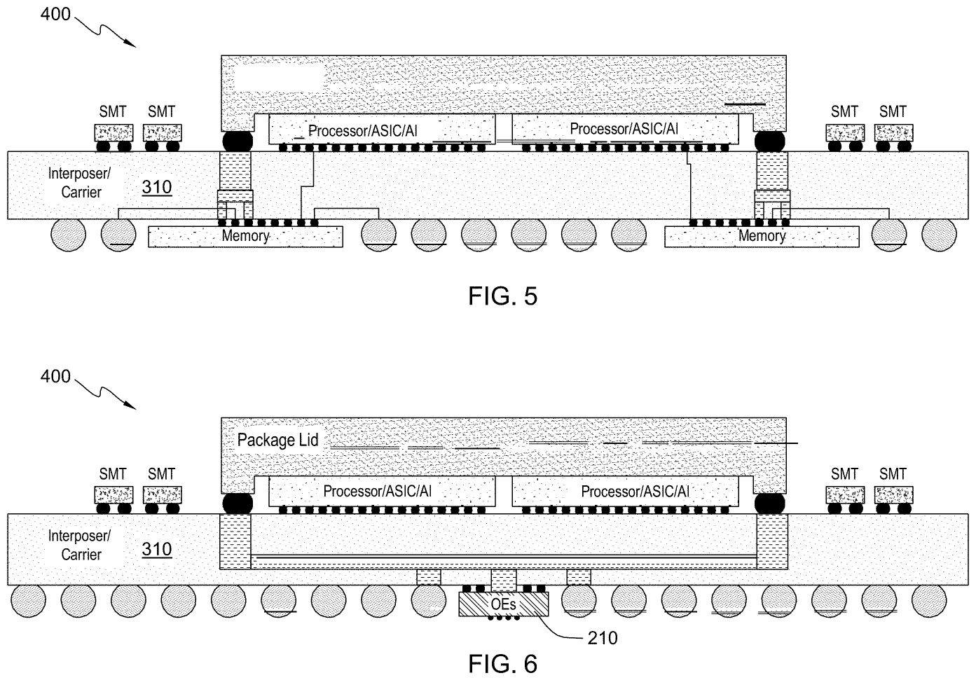

Referring to FIG. 5, a package 400 includes an optical element (OE) for electrical and optical communications on the device, and includes the chip 300 (illustrated in FIG. 3) in cross-section along line B-B′. Referring to FIG. 6, a package 400 includes an optical element (OE) for electrical and optical communications on the device, and includes the chip 300 (illustrated in FIG. 3) in cross-section along line C-C′. According to an embodiment of the present disclosure, on-board optics can be used through a flexible PCB board.

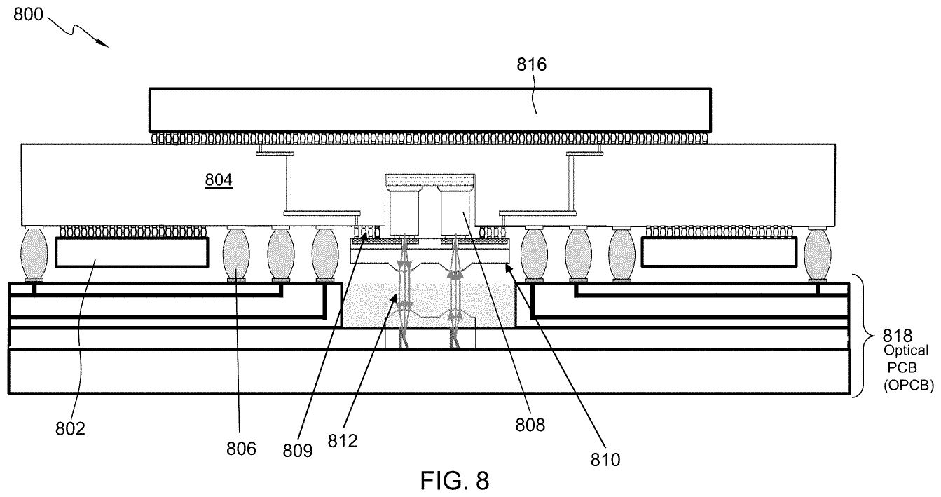

Referring to FIGS. 5 and 6, and package 400, embodiments of the present disclosure can include electrical signals which can go through transmission lines of an interposer/carrier, for example, interposer/carrier 310. An optical laser array in close proximity to a processor/ASIC/AI chips which can eliminate TOSA/ROSA (transmitter optical sub-assembly/receiver optical sub-assembly), electrical re-drive complexity, cost, and power. A dual lens array, one lens array on the PCB, and one lens array on the package, 304, can provide optical collimating for larger alignment tolerances to/from a waveguide located on a PCB. Thermal dissipation can be employed via a top side TIM/heat spreader/heat fin and interposer/carrier Cu (Copper) thermal pipe. Bottom side chips, for example, memory 402 or memory chip, for example, a HBM (High Bandwidth Memory) chip (802 as shown in FIG. 8) and optics, can have an additional thermal conduction path via PCB Cu. The package 400 provides a 3D (three-dimensional) cooling structure with no material or fabrication changes and makes it possible for O/E 210 mounting on an underside of an interposer/carrier.

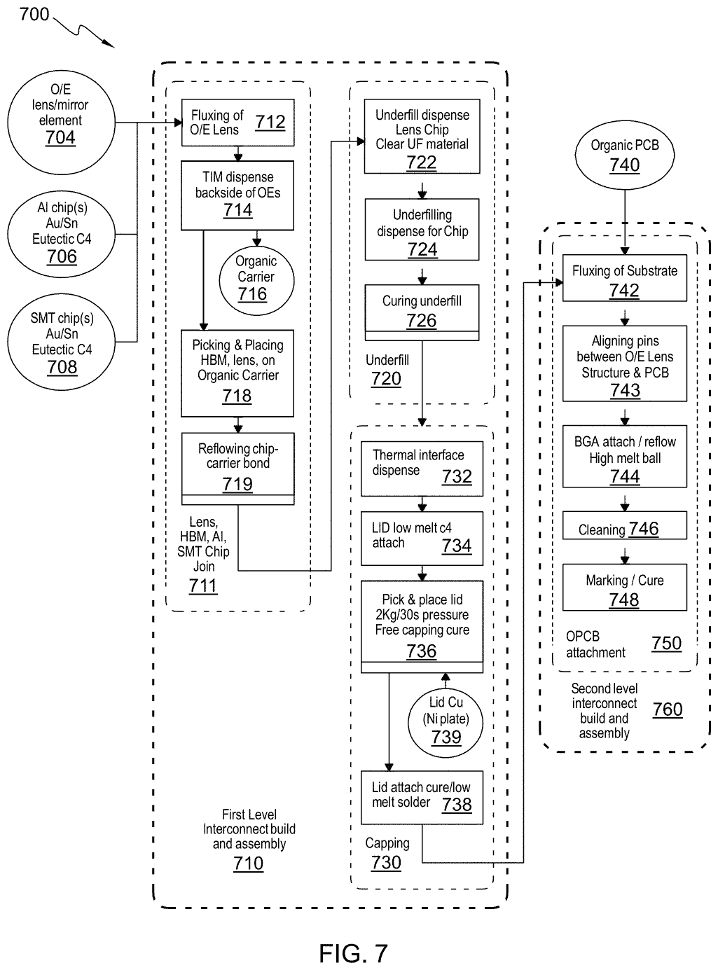

Referring to FIGS. 7 and 8, in FIG. 7, a method 700 of manufacture is depicted for a programmable AI chip, module and card assembly which includes an O/E 808 as part of a lens array 810 for electrical and optical communications on a device, interconnected via a wiring layer 809. In FIG. 8, a chip package 800 depicts elements resulting from the method 700, for using an optical element (OE) for electrical and optical communications on the device. Again referring to FIGS. 7 and 8, in general, the method includes a first level interconnect build and assembly 710, which includes an O/E/lens 712 assembly onto the organic carrier in addition to any semiconductor chips such as memory 802 and AI (Artificial Intelligence) chip (not shown), and any other SMT (surface mount technology) chip join 711 such as capacitors, and underfill 720, and capping 730, and including a second level interconnect build and assembly 760, including an OPCB 818 (Optical Printed Circuit Board) attachment 750. The interposer/carrier 804 can be connected to the OPCP using ball grid array (BGA) using solder balls 806. On-board E/Os 808 conversion (emit/receive) optical signals 812 which includes coupling to off-board (e.g., printed circuit board (PCB)) or flex board.

Referring to FIG. 7, the method 700 includes receiving chips such as an O/E lens/mirror element at block 704. The method includes receiving additional other chips such as an AI chip, for example with Au/Sn (Gold/Tin) eutectic solder for C4 bonding, as in block 706. The method includes receiving SMT (surface mount technology) chip(s), for example with Au/Sn eutectic C4 bonding, as in block 708. The method includes fluxing of the O/E lens, or chips, and C4 spraying process via a mask with a no clean flux or other means, as in block 712. The method includes TIM (thermal interface materials) dispensing on a backside of the OEs, as in block 714. An organic carrier can be received for the TIM dispensing in block 716. The method includes picking and placing chips such as HBMs, E/O/lens on the bottom side of an organic carrier, and other chips such as AI and SMTs on the top side of an organic carrier as in block 718. The method includes reflowing chip carrier bond, for example using Au—Sn eutectic, or any other low or regular temperature melt solder as in block 719. The method includes underfilling the E/O/lens chip as in block 722, for example with a clear underfill material, as in block 722. The method includes underfilling non-optical chips with a structural underfill material, as in block 724. The method includes oven curing the underfill, for example, 150 degrees Celsius for 2 hours, at block 726.

The method 700 further includes dispensing the thermal interface at block 732.

Attaching a lid using a low melt C4 process than prior solder reflow melts is accomplished at block 734. The method includes picking and placing the lid, as in block 736, for example using 2 Kg/30s pressure with a free caping cure. A lid can be provided at block 739, for example, a Cu (Copper) (Ni (Nickel) plate). The method includes attaching the lid using a cure/flow melting solder. For example, a cure process of 125°/150° using forced convection, as in block 738.

The method includes fluxing of a substate, as in block 742, which can include providing an organic PCB (printed circuit board) as in block 740. The method includes alignment, for example with aligning pins or precision placement between O/E lens structures and the PCB, as in block 743. The method includes attaching BGA (Ball Grid Array) using reflow high melt balls, as in block 744. The method includes cleaning at block 746, and marking and curing at 748.

Again referring to FIG. 8, a chip package 800 depicts elements resulting from the method 700. A chip 802 is attached to an interposer/carrier 804. Processors are attached to the interposer 804. A package lid 816 is attached to the interposer 804 and over the processors. An OE structure including O/Es/lenses 808 are aligned and attached to optically emit and receive optical signals 812 to the OPCB optical waveguides or fibers.

In the present disclosure embodiments according to the present disclosure include an effective option to reduce power consumption by bringing optic elements closer to a host chip in order to eliminate intermediate interface layer circuitry and elements. One or more host chips will directly drive the optical devices using either single-ended or differential electrical interconnects. In one embodiment, an optical chip can be mounted on a first level package but does not need any additional processing or connectors such as waveguides or fibers. The first level package continues to be treated like an all electrical interconnect package. Because of the contained first level, all electrical interconnects enable integrated optical interconnects off the first level package. This offers a more reliable and lower latency path, which can increase data rates between packages/boards, as well as lower power consumption.

In another embodiment according to the present disclosure, a multiplexer can provide a round-robin link training scheduling and fault identification. This embodiment includes a separate queue for every data flow. The data flow may be identified by its source and destination address. Algorithms allow active data flow that has data packets in the queue to take turns in transferring packets, for example, on a shared channel, and in a periodically repeated order. The scheduling can be work-conserving. For example, if one flow is out of packets, or a link is down, the next data link will take its place. The priority is to prevent link resources from going unused while identifying faulty links. This reduces stand-by partially on VCSEL power dissipation with no data transmitted.

In another example, more reduction of power and IO area can be achieved using a source synchronous link, such as a clock signal being transmitted along with a wide data bus. In another example, per lane clock recovery is not required in the host chip receiver, which leads to significant power saving and IO area reduction. In another example, an architecture as in the embodiments of the present disclosure can depict a lane sparing technique used in the receiver core to train all the receiver lanes in a round-robin fashion using a single link logic macro shared across the bus. In one embodiment, in a first level package, a processor directly driving optical devices packaged in close proximity can have no intermediate electrical interface, and a forwarded clock.

In another embodiment according to the present disclosure, a semiconductor device includes an optical element (OE) structure for electrical and optical communications on the device. The device can include a semiconductor substrate which includes a wiring layer with an optically transparent path which allows optical signals to pass therethrough. An optical coupling layer coupled to the wiring layer, the optical coupling layer includes at least one micro-lens for focusing or collimating the optical signals through the transparent path. The device includes a carrier being electrically attached to the wiring layer. One or more bonding pads can electrically attach the wiring layer to a carrier at one end of the wiring layer. The device includes a first OE coupled to another end of the wiring layer with respect to the one or more bonding pads. The first OE is positioned in optical alignment with the optically transparent path for communicating optical signals.

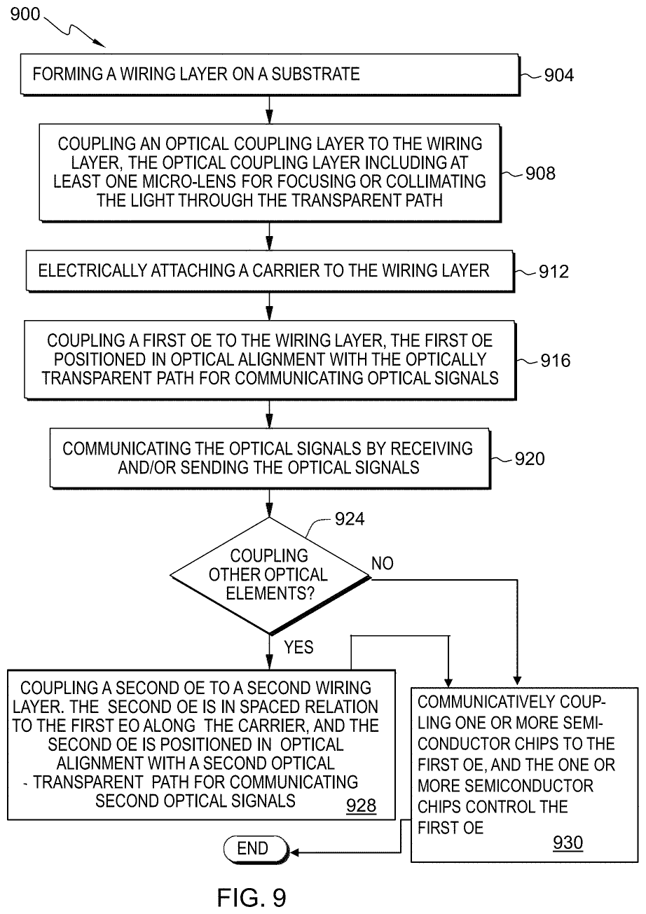

Referring to FIG. 9, a method 900 includes optical element (OE) alignment to a lens array on a substrate assembly for electrical and optical communications, according to embodiment of the present disclosure including forming a wiring layer on a substrate, as in block 904. The substrate may be of semiconductor, an organic, glass, etc. The wiring layer including an optically transparent path which allows optical signals to pass therethrough. The method includes coupling an optical coupling layer to the wiring layer, the optical coupling layer including at least one micro-lens for focusing or collimating the optical signals through the transparent path, as in block 908. The method includes electrically attaching a carrier to the wiring layer, as in block 912. The method includes coupling a first OE to the wiring layer, the first OE positioned in optical alignment with the optically transparent path for communicating optical signals, as in block 916. The method includes communicating of the optical signals by receiving and/or sending the optical signals, as in block 920.

When no other optical elements are coupled to the wiring layer, the method proceeds to block 930. When other optical elements are coupled to the wiring layer at block 924, the method includes coupling a second OE to a second wiring layer. The second OE is in spaced relation to the first EO along the carrier, and the second OE is positioned in optical alignment with a second optical transparent path for communicating second optical signals, as in block 928. The method 900 includes communicatively coupling one or more semiconductor chips to the first OE, and the one or more semiconductor chips control the first OE, as in block 930.

The method 900 shown in FIG. 9, can be implemented, for example, by a device including semiconductor device elements, for example, which are shown in embodiments depicted in the one or more figures. Such example elements are referred to herein below with respect to an embodiment of the present disclosure of a semiconductor, organic, glass or other material device which can implement the method 900 and includes an optical element (OE) 808 for electrical and optical communications on the device. The device can include a semiconductor substrate 804 which includes a wiring layer with an optically transparent path which allows optical signals to pass therethrough. The device includes an optical coupling layer 810 or lens array 204 (as shown in FIG. 2) coupled to the wiring layer 809 or wiring layer 214 (as shown in FIG. 2), the optical coupling layer includes at least one micro-lens for focusing or collimating the optical signals through the transparent path. The device includes a carrier 804 being electrically attached to the wiring layer 809. The device includes a first OE 808 coupled to the wiring layer, the first OE positioned in optical alignment with the optically transparent path for communicating optical signals 812.

In one example, the communicating of the optical signals includes receiving or sending of the optical signals. In another example, the device includes the electrically attaching of the wiring layer to the carrier using one or more bonding pads.

The device can include the electrically attaching of the wiring layer to the carrier using one or more bonding pads. The one or more bonding pads are attached to one end of the wiring layer, and the first OE element is coupled to another end of the wiring layer with respect to the one or more bonding pads. A second OE can be coupled to a second wiring layer, and the second OE in spaced relation to the first EO along the carrier. The second OE is positioned in optical alignment with a second optical transparent path for communicating second optical signals.

The device can include electrically attaching of the wiring layer to the carrier using one or more bonding pads, and the one or more bonding pads is attached to one end of the wiring layer, and the first OE coupled to another end of the wiring layer with respect to the one or more bonding pads. The device can further include a second OE being coupled to a second wiring layer. The second OE is in spaced relation to the first EO along the carrier, and the second OE is positioned in optical alignment with a second optical transparent path for communicating second optical signals. The communicating of the first and second optical signals can include receiving or sending the first or second optical signals, respectively.

In another embodiment according to present disclosure, a system can include a chip package which includes a semiconductor device which includes an optical element (OE) for electrical and optical communications on the device. The system can include a semiconductor substrate which includes a wiring layer with an optically transparent path which allows optical signals to pass therethrough. An optical coupling layer can be coupled to the wiring layer, and the optical coupling layer can include at least one micro-lens for focusing or collimating the optical signals through the transparent path. The system can include a carrier electrically attached to the wiring layer. A first OE is coupled to the wiring layer, and the first OE positioned in optical alignment with the optically transparent path for communicating optical signals.

In another embodiment according to the present disclosure, a system according and method resulting in a system as described in the present disclosure can include a direct drive optical sub-assembly architecture with s lane sparing technique.

### MORE EXAMPLES AND EMBODIMENTS

Operational blocks and system components shown in one or more of the figures may be similar to operational blocks and system components in other figures. The diversity of operational blocks and system components depict example embodiments and aspects according to the present disclosure. For example, methods shown are intended as example embodiments which can include aspects/operations shown and discussed previously in the present disclosure, and in one example, continuing from a previous method shown in another flow chart.

### FURTHER DISCUSSION REGARDING EXAMPLES AND EMBODIMENTS

It is understood that a set or group is a collection of distinct objects or elements. It is further understood that a set or group can be one element, for example, one thing or a number, in other words, a set of one element, for example, one or more users or people or participants. It is also understood that machine and device are used interchangeable herein to refer to machine or devices in one or more AI ecosystems or environments.

The descriptions of the various embodiments of the present invention have been presented for purposes of illustration, but are not intended to be exhaustive or limited to the embodiments disclosed. Likewise, examples of features or functionality of the embodiments of the disclosure described herein, whether used in the description of a particular embodiment, or listed as examples, are not intended to limit the embodiments of the disclosure described herein, or limit the disclosure to the examples described herein. Such examples are intended to be examples or exemplary, and non-exhaustive. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The flowchart and block diagrams in the Figures of the present disclosure illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A device which includes an optical element (OE) for electrical and optical communications on the device, which comprises:
a substrate which includes a wiring layer with an optically transparent path which allows optical signals to pass therethrough;
an optical coupling layer coupled to the wiring layer, the optical coupling layer includes at least one micro-lens for focusing or collimating the optical signals through the transparent path;
a carrier being electrically attached to the wiring layer;
a first OE coupled to the wiring layer, the first OE positioned in optical alignment with the optically transparent path for communicating optical signals; and
one or more semiconductor chips being communicatively coupled to the first OE, wherein the one or more semiconductor chips control the first OE.

2. The device of claim 1, wherein the communicating of the optical signals includes receiving or sending of the optical signals.

3. The device of claim 1, wherein the electrically attaching of the wiring layer to the carrier includes using one or more bonding pads.

4. The device of claim 1, wherein the electrically attaching of the wiring layer to the carrier includes using one or more bonding pads, and the one or more bonding pads being attached to one end of the wiring layer, and the first OE element coupled to another end of the wiring layer with respect to the one or more bonding pads.

5. The device of claim 1, which further comprises:
a second OE being coupled to a second wiring layer, the second OE in spaced relation to the first EO along the carrier, and the second OE being positioned in optical alignment with a second optical transparent path for communicating second optical signals; and
another one or more semiconductor chips being communicatively coupled to the second OE, wherein the another one or more semiconductor chips control the second OE.

6. The device of claim 1, wherein the electrically attaching of the wiring layer to the carrier includes using one or more bonding pads, and the one or more bonding pads being attached to one end of the wiring layer, and the first OE coupled to another end of the wiring layer with respect to the one or more bonding pads; and the device further comprises:
a second OE being coupled to a second wiring layer, the second OE in spaced relation to the first EO along the carrier, and the second OE being positioned in optical alignment with a second optical transparent path for communicating second optical signals; and
another one or more semiconductor chips being communicatively coupled to the second OE, wherein the another one or more semiconductor chips control the second OE.

7. The device of claim 6, wherein the communicating of the first and second optical signals includes receiving or sending the first or second optical signals, respectively.

8. A method of optical element (OE) alignment to a lens array for electrical and optical communications, comprising:
forming a wiring layer on a semiconductor substrate, the wiring layer including an optically transparent path which allows optical signals to pass therethrough;
coupling an optical coupling layer to the wiring layer, the optical coupling layer including at least one micro-lens for focusing or collimating the optical signals through the transparent path;
electrically attaching a carrier to the wiring layer;
coupling a first OE to the wiring layer, the first OE positioned in optical alignment with the optically transparent path for communicating optical signals; and
communicatively coupling one or more semiconductor chips to the first OE, wherein the one or more semiconductor chips control the first OE.

9. The method of claim 8, further comprising:
receiving or sending of the optical signals as part of the communicating of the optical signals.

10. The method of claim 8, wherein the electrically attaching of the wiring layer to the carrier includes using one or more bonding pads.

11. The method of claim 8, wherein the electrically attaching of the wiring layer to the carrier includes using one or more bonding pads, and the method further including:
attaching the one or more bonding pads to one end of the wiring layer, and coupling the first OE element to another end of the wiring layer with respect to the one or more bonding pads.

12. The method of claim 8, further comprising:
coupling a second OE to a second wiring layer, the second OE in spaced relation to the first EO along the carrier;
positioning the second OE in optical alignment with a second optical transparent path for communicating second optical signals; and
communicatively coupling another one or more semiconductor chips to the second OE, wherein the another one or more semiconductor chips control the second OE.

13. The method of claim 8, wherein the electrically attaching of the wiring layer to the carrier includes using one or more bonding pads; and the method further comprising:
attaching the one or more bonding pads to one end of the wiring layer;
coupling the first OE to another end of the wiring layer with respect to the one or more bonding pads;
coupling a second OE to a second wiring layer, the second OE in spaced relation to the first EO along the carrier;
positioning the second OE in optical alignment with a second optical transparent path for communicating second optical signals; and
communicatively coupling another one or more semiconductor chips to the second OE, wherein the another one or more semiconductor chips control the second OE.

14. The method of claim 13, wherein the communicating of the first and second optical signals includes receiving or sending the first or second optical signals, respectively.

15. A system including a chip package which includes a device which includes an optical element (OE) for electrical and optical communications on the device, which comprises:
a semiconductor substrate which includes a wiring layer with an optically transparent path which allows optical signals to pass therethrough;
an optical coupling layer coupled to the wiring layer, the optical coupling layer includes at least one micro-lens for focusing or collimating the optical signals through the transparent path;
a carrier being electrically attached to the wiring layer;
a first OE coupled to the wiring layer, the first OE positioned in optical alignment with the optically transparent path for communicating optical signals; and
one or more semiconductor chips being communicatively coupled to the first OE, wherein the one or more semiconductor chips control the first OE.

16. The system of claim 15, wherein the communicating of the optical signals includes receiving or sending of the optical signals.

17. The system of claim 15, wherein the electrically attaching of the wiring layer to the carrier includes using one or more bonding pads.

18. The system of claim 15, wherein the electrically attaching of the wiring layer to the carrier includes using one or more bonding pads, and the one or more bonding pads being attached to one end of the wiring layer, and the first OE element coupled to another end of the wiring layer with respect to the one or more bonding pads.

19. The system of claim 15, which further comprises:
a second OE being coupled to a second wiring layer, the second OE in spaced relation to the first EO along the carrier, and the second OE being positioned in optical alignment with a second optical transparent path for communicating second optical signals; and
another one or more semiconductor chips being communicatively coupled to the second OE, wherein the one or more semiconductor chips control the second OE.

20. The system of claim 15, wherein the electrically attaching of the wiring layer to the carrier includes using one or more bonding pads, and the one or more bonding pads being attached to one end of the wiring layer, and the first OE coupled to another end of the wiring layer with respect to the one or more bonding pads; and the device further comprises:
a second OE being coupled to a second wiring layer, the second OE in spaced relation to the first EO along the carrier, and the second OE being positioned in optical alignment with a second optical transparent path for communicating second optical signals; and
another one or more semiconductor chips being communicatively coupled to the second OE, wherein the another one or more semiconductor chips control the second OE.
